(19) United States
(12) Patent Application Publication
(10) Pub. No.: US 2013/0124117 A1
(43) Pub. Date: May 16, 2013

(54) ELECTRIC VEHICLE AND METHOD OF DIAGNOSING CURRENT SENSOR

(71) Applicants: Yoshihiro NOMURA, Toyota-shi (JP); Masahiro NISHIU, Toyohashi-shi (JP)

(72) Inventors: Yoshihiro NOMURA, Toyota-shi (JP); Masahiro NISHIU, Toyohashi-shi (JP)

(21) Appl. No.: 13/669,802

(22) Filed: Nov. 6, 2012

(30) Foreign Application Priority Data
Nov. 14, 2011 (JP) 2011-248969

(51) Int. Cl. G06F 19/00; G01R 31/28

(52) U.S. Cl. 702/58; 702/64

(57) ABSTRACT

An electric vehicle includes: a battery that stores electric power to be supplied to a traction motor; a current sensor that measures a charging current and a discharging current flowing to and from the battery; and a controller configured to monitor a measurement value of the current sensor during a period of time, during which a main switch of the electric vehicle is at an ON position and a power generation motor is at a stop, and configured to, when the measurement value indicates that the charging current is flowing to the battery, output, to at least one of a display unit and a memory, data indicating that the charging current is flowing.

### INCORPORATION BY REFERENCE

The disclosure of Japanese Patent Application No. 2011-248969 filed on Nov. 14, 2011 including the specification, drawings and abstract is incorporated herein by reference in its entirety.

### BACKGROUND OF THE INVENTION

1. Field of the Invention

The present invention relates to an electric vehicle including a traction motor and a method of diagnosing a current sensor provided on the electric vehicle. “The electric vehicle” mentioned in this specification includes a hybrid vehicle including the traction motor and an engine as well.

2. Description of the Related Art

In recent years, hybrid vehicles including a traction motor and an engine have been prevailing rapidly. It is estimated that in a near future, an electric vehicle that can travel with only a motor without any engine (what is called a pure electric vehicle) will prevail explosively. A battery for supplying electricity to the traction motor is a high-power, large-capacity battery. That is, the electric vehicles including the hybrid vehicles handle a large current. Thus, regarding the electric vehicle, a variety of technologies for detecting a fault in their electric system have been proposed. For example, Japanese Patent Application Publication No. 2005-269752 (JP 2005-269752 A) has proposed a technology for detecting a fault in charge/discharge of a battery that supplies electric power to the traction motor. According to JP 2005-269752 A, two kinds of current sensors for measuring charging/discharging current of the battery are provided and an integrated value of the charging/discharging current of the battery is obtained with each of the two kinds of the current sensors, and, when any of the two integrated value is larger than a set value, it is determined that a fault has occurred in the battery.

A method in which the same object (a battery charging/discharging current in the above case) is measured with two sensors to increase the reliability of the sensor has been often used. As another approach for increasing the reliability of the sensor, a method of detecting a fault in the sensor itself has been sometimes employed. For example, as one of the detections of a fault in the current sensor itself employed in the electric vehicle, detecting an offset fault is performed. In this case, the battery is disconnected from the electric system of a vehicle, and measurement values of the current sensor are monitored in a situation where no current flows through a circuit. When the current sensor indicates a value other than zero, that value is specified as an offset. In the meantime, a relay (switch) that connects/disconnects the battery to/from the electric system of a vehicle is called a system main relay.

To detect a fault in the system, it is necessary to check soundness (proper functioning) of the sensor. The current sensor is one of important sensors in the electric vehicle that handles a large current, and increasing the reliability of the current sensor or checking the soundness of the current sensor is important. The technology proposed in JP 2005-269752 A, which is one of those technologies, cannot cope with shortage of electric power supplied to the current sensor, for example. The reason is that when supply of electric power is short, any one of both the two current sensors does not indicate a right measurement value. Furthermore, technology for determining an offset in the current sensor by opening its system main relay cannot verify whether the current sensor is sound when its circuit is closed. That is, in a situation where current can flow through the current sensor, it is impossible to verify whether the current sensor functions properly. It is easy to detect a fault due to short-circuit in the sensor because the sensor outputs zero or a maximum value in this case. Conversely, any conventional methods cannot detect a fault resulting from other reasons than the short-circuit.

### SUMMARY OF THE INVENTION

The present invention proposes a new technology for diagnosing a current sensor in an electric vehicle. The current sensor for measuring a charging current and a discharging current in the battery is an important current sensor for monitoring the charging current and the discharging current in the battery, the current sensor being built in a battery pack or between the battery pack and a system main relay. For the important current sensor for measuring the charging current and the discharging current in the battery, the present invention provides a technology for detecting a fault in the current sensor itself that cannot be detected by a method using the data from two sensors or a method of detecting an offset.

According to a first aspect of the present invention, an electric vehicle includes: a battery that stores electric power to be supplied to a traction motor; a current sensor that measures a charging current and a discharging current flowing to and from the battery; and a controller configured to monitor a measurement value of the current sensor during a period of time, during which a main switch of the electric vehicle is at an ON position and a power generation motor is at a stop, and configured to, when the measurement value indicates that the charging current is flowing to the battery, determine that a fault has occurred in the current sensor and output, to at least one of a display unit and a memory, the data (error message) indicating that the charging current is flowing. That is, the controller has a function of checking a state of the current sensor. “The power generation motor” may serve as “a traction motor” or may be a motor dedicated to power generation. Furthermore, the above-mentioned electric vehicle may be a pure electric vehicle provided with no engine or may be a hybrid vehicle provided with both a traction motor and an engine.

According to the present invention, a situation, in which, although the battery is connected to an electric circuit such as an inverter and current can therefore flow, essentially no current could flow, is specified, and then a measurement value of the current sensor is monitored under such a situation. If the current sensor indicates any value which essentially it could not indicate, it is found that a fault has occurred in the current sensor. This method aims at determining whether or not, in a situation in which an electric system is closed (in other words, in a situation in which current can flow into the current sensor), the measurement value of the current sensor indicates any abnormal value, thereby making it possible to detect a fault in a current sensor and the circuit system that contributes to the operation of the current sensor.

The above-mentioned electric vehicle specifies a situation, in which the battery is connected to the inverter and the current sensor could not measure any charging current flowing to the battery if the current sensor is properly operating, is specified as follows. First, a vehicle main switch is at an ON position. Generally, “the vehicle main switch” refers to an ignition switch, a power switch, or a switch called a main switch, which is a switch for turning the vehicle into a state, in which the vehicle can run or travel. Hereinafter, in this specification, such a switch will be called a main switch for simplicity. When the main switch is at the ON position, a system main relay for connecting the battery to the electric system (typically, inverter) of the vehicle is closed, so that the electric system turns into a closed circuit. That is, a situation in which current can flow through the current sensor for measuring the charging/discharging current to/from the battery is brought about. Second, the power generation motor is at a stop. During a rotation of the power generation motor, the charging current can flow to the battery. Because generation of power is disabled during a stop of the power generation motor, no charging current could flow to the battery. However, because some devices in the vehicle consume electric power, discharging current in a direction of coming out from the battery can flow out. Therefore, when under the above-described two conditions (condition in which the main switch is at the ON position and condition in which the power generation motor is at a stop), the measurement value of the current sensor indicates that the charging current is flowing toward the battery, it can be determined that a fault has occurred in the current sensor or a circuit relating to the current sensor. The controller of the electric vehicle outputs data indicating that a fault has occurred to the display unit or the memory. In the meantime, “the display unit or the memory” mentioned here may be a display unit etc. mounted on a vehicle or a display unit etc. provided externally to the vehicle, for example, a computer provided at a service center for remote service for monitoring a state of the vehicle wirelessly. Particularly, data recorded in the memory mounted on a vehicle or a computer at a service center is used as diagnosis data which a service staff checks at the time of vehicle maintenance.

According to a second aspect of the present invention, a method of diagnosing a current sensor, provided on an electric vehicle including a battery, that measures a charging current and a discharging current to and from the battery that stores electric power to be supplied to a traction motor includes: monitoring a measurement value of the current sensor during a period of time, during which a main switch of the electric vehicle is at an ON position and a power generation motor is at a stop; and, when the measurement value indicates that the charging current is flowing to the battery, outputting, to at least one of a display unit and a memory, data indicating that the charging current is flowing.

A detail of the present invention and further improvements will be described in the description of embodiments thereof.

### BRIEF DESCRIPTION OF THE DRAWINGS

The features, advantages, and technical and industrial significance of this invention will be described in the following detailed description of example embodiments of the invention with reference to the accompanying drawings, in which like numerals denote like elements, and wherein:

FIG. 1 is a block diagram illustrating an electric system of an electric vehicle according to an embodiment of the present invention;

FIG. 2 is a flow chart of a current sensor check process to be executed by a controller; and

FIG. 3 is a time chart of sensor data for illustrating a state of processing of the controller.

### DETAILED DESCRIPTION OF EMBODIMENTS

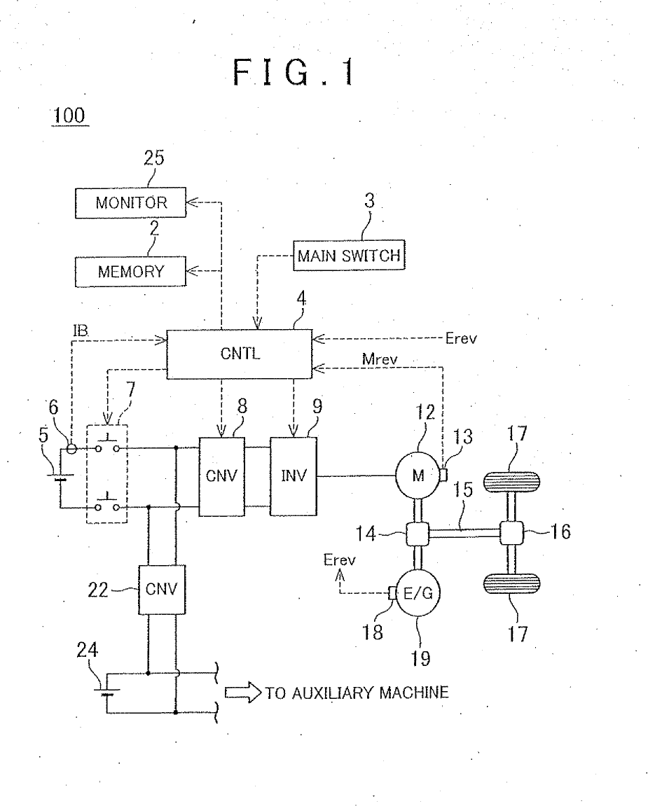

FIG. 1 illustrates a block diagram of an electric system of a vehicle according to an embodiment. The vehicle of the present embodiment is a hybrid vehicle 100 equipped with a traction motor and an engine. It should be noted that FIG. 1 does not illustrate all units that the hybrid vehicle 100 is essentially equipped with. FIG. 1 illustrates units that relate to technical description of the present embodiment.

A battery 5 mounted on the hybrid vehicle 100 is, for example, a high-power, large-capacity battery having a maximum output voltage of 300 V and a maximum output current of 200 A, that is, a maximum output power of 60 kW. The battery 5 is, for example, a lithium-ion battery. A maximum output power required of the battery 5 depends on the maximum output power of a mounted motor 12. In the present embodiment, the maximum output power of the motor 12 is 60 kW. Correspondingly, the battery 5 having a maximum output power of 60 kW is employed. In addition to the high-power, large-capacity battery 5A, a hybrid vehicle 100 includes a battery 24 of 12 V that corresponds to a battery of ordinary engine vehicles. To distinguish between the both, hereinafter, the high-power, large-capacity battery capable of storing electric power for driving the traction motor 12 is referred to as the main battery 5, and a battery having a relatively low output voltage of 12 V is referred as sub-battery 24.

A main battery 5 is connected to a first converter 8 via a system main relay 7. The system main relay 7 is a relay that connects or disconnects the battery 5 to/from an electric system of a vehicle and is controlled by a controller 4. The first converter 8 is a DC-DC converter that is a device for stepping up a direct-current (DC) output voltage of 300 V from the battery 5 to an appropriate voltage suitable for driving a motor (e.g., 600 V). A DC power stepped up by the first converter 8 is input to an inverter 9. The inverter 9 converts the DC power to alternating-current (AC) power for use in driving the motor 12, which is output to the motor 12. Both the first converter 8 and the inverter 9 have a switching circuit for conversion of electric power. The switching circuit is a combination of a power transistor such as an insulated gate bipolar transistor (IGBT) with a diode (freewheeling diode). The controller 4 sends an instruction to each switching circuit of the first converter 8 and the inverter 9. The instruction is a pulse-width-modulation (PWM) signal and by its duty ratio, the output voltage (in the case of the converter) or the frequency of the output current (in the case of the inverter) is controlled. Detailed description about internal structures of the converter and the inverter is omitted because they are well known. The inverter 9 has a function of converting electric power (regenerative electric power that is AC electric power) generated by the motor 12 with braking energy of the vehicle to DC power. Furthermore, the first converter 8 has a function of stepping down the voltage of the regenerative power converted to DC current to an appropriate voltage for the main battery 5. At the time of regeneration, the motor 12 functions as a generator. The inverter 9 converts AC power generated by the motor 12 to DC power and the converter 8 converts the DC power to an appropriate voltage for charging the main battery 5.

The main battery 5 is also connected to a second converter 22 via the system main relay 7. The second converter 22 is a DC-DC converter for stepping down the output voltage (e.g., 300 V) of the main battery 5 to an appropriate voltage (e.g., 12 V) for driving other electronic devices. The second converter 22 supplies electric power to devices that are driven at a low voltage of 12 V. The devices driven at 12 V include, for example, a room light, a car audio player, and a car navigation system. A variety of controller circuits mounted on a vehicle is also included in the device driven at 12 V. The controller 4, which generates a PWM signal that is an instruction for the first converter 8, the second converter 22 and the inverter 9, is one of the devices driven at 12 V. Hereinafter, a group of the devices driven at 12 V is collectively called the “auxiliary machine”.

The output of the second converter 22 is sent to a 12-V sub-battery 24 also. That is, using electric power from the high-power, large-capacity main battery 5, charging of the sub-battery 24 and supply of electricity to other devices to be driven at 12 V are carried out. The 12-V sub-battery 24 aims at supplying electric power to the other devices to be driven at 12 V when they cannot receive supply of electricity from the main battery 5. That is, while the system main relay 7 is open, the sub-battery 24 supplies electric power to the other devices to be driven at 12 V.

A drive mechanism of the hybrid vehicle 100 will be described below. The hybrid vehicle 100 uses the motor 12 and the engine 19 selectively depending on a purpose. An output shaft of the motor 12 and an output shaft of the engine 19 are connected via a power distribution mechanism 14 and a synthesized torque is transmitted to an axle 15. The axle 15 is driven together with a drive wheel 17 via a differential 16. When a large drive force is required, both the engine 19 and the motor 12 are driven. The output torques thereof are synthesized by the power distribution mechanism 14 and the synthesized torque is transmitted to the drive wheel 17 via the axle 15. When not so large torque is required, that is, for example, when a vehicle travels at a constant velocity, the engine 19 is stopped and the drive wheel 17 is driven with only the motor 12. On the other hand, if the remaining charge of the main battery 5 decreases, the engine 19 is started and torque of the engine 19 is distributed to the axle 15 and the motor 12 by the power distribution mechanism 14. While the drive wheel 17 is driven by the output torque from the engine 19, the motor 12 is driven to generate electricity. When a vehicle driver depresses a brake pedal, the axle 15 is connected directly to the motor 12 so that the motor 12 is driven inversely by its output shaft with kinetic energy of the vehicle to generate electricity. That is, the hybrid vehicle 100 converts the kinetic energy of the vehicle to electric energy and charges the main battery 5 with the electric power. The power distribution mechanism 14 is a planetary gear and its sun gear is connected to the motor 12. Further, a planetary carrier is connected to the engine 19 and its ring gear is connected to the axle 15. The motor 12 and the engine 19 are controlled by the controller 4. In the meantime, the hybrid vehicle 100 actually includes a number of controllers having their respective functions, and the controllers cooperatively operate to make the entire vehicle function as a single vehicle system. To simplify description of this specification, those controllers are generally referred to as the “controller 4”0 although actually, they are physically divided to a plurality of the controllers.

The motor 12 is provided with a rotational speed sensor 13 for measuring its rotational speed Mrev and the engine 19 is provided with a rotational speed sensor 18 for measuring its rotational speed Erev. The output of each rotational speed sensor is sent to the controller 4.

Next, a main switch 3 of the vehicle provided at the driver's seat will be described. The main switch 3 is a switch for selecting a basic state of the vehicle and corresponds to an ignition key switch of a conventional gasoline vehicle. Although in the conventional gasoline vehicle, its engine can be started by turning on the ignition key, the hybrid vehicle can run with the engine stopped and the engine is not always started soon after the main switch 3 is turned on. The main switch 3 switches the vehicle to any one of following four states. (1) OFF state: all the vehicle system is stopped except always-operating units that are part of the vehicle system, such as a security unit and a clock. (2) ACC state: electricity is supplied to electronic devices, such as a radio and a car navigation system, except the drive system. No large electric power (electric power of the main battery 5) for driving the motor is supplied. That is, the system main relay 7 for connecting the main battery 5 to a drive electric system remains open. (3) IG-ON state: electricity is supplied from the main battery 5 to the drive system (more specifically, at least one of the first converter 8, the second converter 22, and the inverter 9). That is, in this state, the system main relay 7 is closed. However, the vehicle still cannot run. The controller 4 does not accept an operation of the drive system except the main switch 3. For example, in the IG-ON state, a shift lever is permitted to be only at parking (P) position and neutral (N) position. That is, a vehicle driver cannot move the shift lever to drive (D) position. Therefore, the vehicle does not start even if the vehicle driver depresses an accelerator pedal. Typically, “operating the drive system” is operating the shift lever to the D position or the reverse (R) position or operating the accelerator pedal. (4) READY-ON state: the vehicle is capable of traveling. When the shift lever is moved to the D (drive) position and the accelerator pedal is depressed, the vehicle starts traveling.

When the main switch is at the OFF position or the ACC position, the system main relay 7 remains open. That is, the main battery 5 is disconnected from the drive system (more specifically, at least one of the first converter 8, the second converter 22, and the inverter 9). When the main switch 3 is at IG-ON position or READY-ON position, the system main relay 7 is closed. That is, the main battery 5 is connected to the drive system. Hereinafter, when the main switch 3 is at the OFF position or the ACC position where the system main relay 7 is open, it is simply stated that “the main switch is at the OFF position”. When the main switch 3 is at the IG-ON position or the READY-ON position where the system main relay 7 is closed, it is simply stated that “the main switch is at the ON position”.

As described above, when the main switch 3 is at the ON position, the system main relay 7 is closed, so that the main battery 5 is connected to the drive system, thereby allowing current to flow.

As described above, a large current exceeding 100 A can flow from the main battery 5. Thus, a current sensor 6 is provided in the vicinity of the battery 5 (more specifically, closer to the battery than to the system main relay 7) for the controller 4 to always monitor a charging/discharging current of the main battery 5. The current sensor 6 is an important sensor because it measures a large current. When a fault occurs in the current sensor 6, the drive system of the hybrid vehicle 100 does not function properly. Thus, it is important to detect a fault in the current sensor 6 (evaluate the reliability). Although not mentioned in the present embodiment, making a redundancy system by providing two current sensors is an idea for detecting a fault in the current sensor (or improvement of the reliability of current sensor output). Furthermore, a fault that a terminal of the current sensor 6 short-circuits with a ground line or a power supply line can be detected relatively easily. However, although the output of the current sensor 6 changes according to the flowing current, it is difficult to confirm whether a proper output proportional to the magnitude of the flowing current is produced. The hybrid vehicle 100 of the present embodiment is provided with a technology of verifying whether the current sensor 6 is activated properly even when the main battery 5 and the drive system (inverter 9, etc.) are connected and current can flow through the current sensor 6. Hereinafter, a technology for checking the current sensor 6 will be described.

As described above, when the main switch 3 of the vehicle is switched to the ON position, the system main relay 7 is closed, so that the main battery 5 is connected to the drive system and current can flow through the current sensor 6. For example, as described above, an output of the second converter 22 is supplied to the auxiliary machine. The auxiliary machine includes the controller 4. While the main battery 5 is disconnected, electric power is supplied from the sub-battery 24 to the controller 4. When the main switch 3 is switched to the ON position, the main battery 5 is connected to the first converter 8 and the second converter 22, so that electric power of the main battery 5 is supplied to the controller 4 via the second converter 22. Thus, a measurement value IB of the current sensor 6 indicates a current flowing out of the main battery 5 (discharge current). Because electric power of 12 V is consumed by other devices as well as the controller 4, the magnitude of current flowing out of the main battery 5 does not remain constant but changes depending on the number and kind of activated electronic devices.

When the motor 12 is driven from the output shaft side to generate electric power (regenerative electric power), the regenerative electric power flows to the main battery 5 so that the main battery 5 is charged. At this time, the measurement value IB of the current sensor 6 indicates a current flowing into the main battery 5 (charging current). The controller 4 (of the hybrid vehicle 100) monitors the measurement value IB of the current sensor 6 in a situation where the generator motor (motor 12) is not rotated and the charging current could therefore not flow to the main battery 5, and, when the measurement value IB indicates that the charging current flows to the main battery 5, the controller 4 determines that a fault has occurred in the current sensor 6. More specifically, when the measurement value of the current sensor 6 indicates that a larger charging current than a predetermined current threshold flows to the main battery 5 for a period of time longer than a predetermined time threshold, the controller 4 determines that a fault has occurred in the current sensor 6. Here, the time threshold and the current threshold are measures for preventing an error in determination due to noise and the like. When the above determination is made, the controller 4 displays data (error message) indicating the determination result on a monitor 25 (instrument panel) of the vehicle and writes it into a memory 2. The memory 2 is nonvolatile and written data does not disappear even if the power is turned off. The memory 2 is a memory for storing conditions of the vehicle, and the stored conditions of the vehicle are read in maintenance service of the hybrid vehicle 100 and used for diagnosis of the vehicle. In general, such data is called diagnostic data.

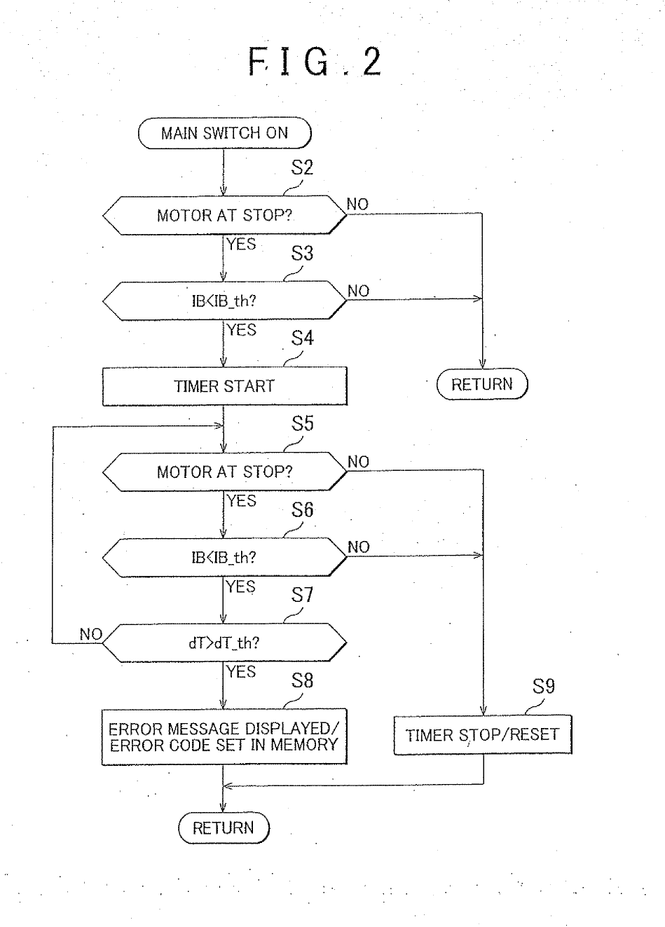

FIG. 2 illustrates a flow chart of a process of checking the current sensor 6. The process shown in FIG. 2 is carried out by the controller 4. The process shown in FIG. 2 is executed periodically when the main switch 3 is at the ON position. When the motor 12 is rotating, the controller 4 terminates the process shown in FIG. 2 without doing anything (S2: NO). When the motor 12 is at a stop, the controller 4 executes the process from step 3 onward (S2: YES). In the meantime, the motor 12 serves for both traveling and power generation because it drives wheels in some cases, and it generates electric power with kinetic energy of the vehicle in some cases. Therefore, the process of step S2 is equivalent to determining whether the power generation motor 12 is at a stop.

When the motor 12 is at a stop (S2: YES), the controller 4 checks whether a measurement value IB of the current sensor 6 is smaller than a predetermined current threshold IB_th (S3). Here, current (discharging current) flowing out of the main battery 5 is expressed by a positive value, and current (charging current) flowing into the main battery 5 is expressed by a negative value. Therefore, the measurement value IB smaller than the current threshold IB_th (<0) indicates that larger current than the predetermined current threshold IB_th is flowing into the main battery 5. When determination in step S3 is NO, the process is terminated without doing anything. On the other hand, when the measurement value IB is smaller than the current threshold IB_th (S3: YES), the controller 4 starts the timer (S4). This timer measures a duration time dT of a state, in which the measurement value IB is smaller than the current threshold IB_th. After that, the controller 4 waits until the motor begins to rotate (S5: NO) or until the measurement value IB exceeds the current threshold IB_th (S6: NO) or until the duration time dT reaches the predetermined time threshold dT_th (S7: YES). When the motor 12 remains at a stop (S5: YES) and at the same time, a state in which the measurement value IB of the current sensor 6 remains below the current threshold IB_th for a period of time longer than the time threshold dT_th (S7; YES), the controller 4 determines that a fault has occurred in the current sensor 6, displays an error message indicating its determination result on the monitor 25 of the vehicle, and records an error code indicating the determination result into the memory 2 (S8). On the other hand, if the motor begins to rotate before the duration time dT elapses (S5: NO) or the measurement value IB exceeds IB_th (S6: NO), it is determined that the reason why the measurement value IB is smaller than the current threshold IB_th is due to a temporary event such as noise and then, the timer is stopped and reset (S9), thereby finishing the process. In the check process shown in FIG. 2, it is determined that the current sensor 6 is operating properly until step 8 is executed.

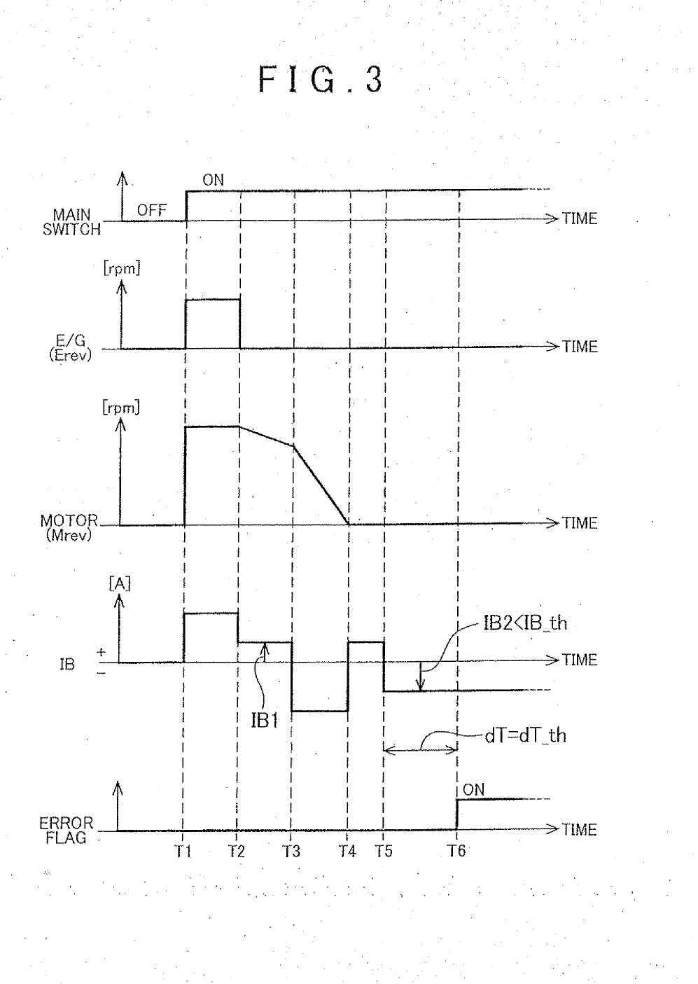

The above process will be described with reference to examples below. FIG. 3 shows a time chart about the rotational speed Mrev of the motor 12, engine rotational speed Erev, and the measurement value IB of the current sensor 6. The rotational speed Mrev of the motor 12 is measured by a rotational speed sensor 13 mounted on the motor 12 and a rotational speed of the engine 19 is measured by the rotational speed sensor 18 mounted on the engine 19. The measured rotational speed data are sent to the controller 4. FIG. 3 also shows a time chart about the state of the main switch 3 and an error flag indicating a result of checking whether any fault has occurred in the current sensor 6. Although in the present embodiment, the engine rotational speed Erev is not used to check the current sensor 6, FIG. 3 shows the Erev data for reference.

First, at time T1, the main switch 3 at the driver's seat is switched from the OFF position to the ON position. After time T1, the system main relay 7 is closed, so that the vehicle 100 is enabled to travel. This operation is performed by a driver, After time T1, the main switch 3 remains at the ON position. When the accelerator pedal (not illustrated) is depressed at time T1, the vehicle begins to travel. In a period from time T1 to T2, both the engine 19 and the motor 12 are activated to transmit a high drive torque to the wheels. In the period from time T1 to T2, the measurement value IB of the current sensor 6 indicates a positive value. That is, the measurement value IB of the current sensor 6 indicates that the main battery 5 is outputting discharge current.

At time T2, the accelerator pedal is released, then, the engine 19 is stopped. Although supply of electricity to the motor 12 is stopped, the rotational speed Mrev of the motor 12 decreases gradually with a drop in vehicle speed, because the motor 12 is connected directly to the axle. In the meantime, in a period from time T2 to T3, during which the accelerator pedal remains released, the measurement value IB of the current sensor 6 indicates a small positive value IB1. This indicates that discharge current is output from the main battery 5. As described above, even if the inverter 9 does not supply electricity to the motor 12, electric power from the main battery 5 flows to the auxiliary machine via the second converter 22. Thus, the measurement value IB of the current sensor 6 indicates a small positive value IB1.

At time T3, the brake pedal is depressed. Then, the inverter 9 is activated to recover regenerative electric power. Back electromotive force is generated in the motor 12, so that induction current flows. The inverter 9 converts the induction current (AC) into direct current. If the inverter 9 draws in the current, the induction current continues to flow. A magnetic field is generated by this induction current and a force of the magnetic field acts in a direction such that a rotation of the motor 12 is stopped. That is, as a result of recovery of the regenerative electric power, the motor 12 exerts a braking force. The direct current obtained by the inverter 9 is input to the first converter 8. The first converter 8 steps down the voltage input from the inverter side and outputs it to the main battery 5 side. That is, the main battery 5 is charged with the regenerative electric power generated by the motor 12. At this time, the measurement value IB of the current sensor 6 turns to a negative value (in a period from time T3 to T4 in FIG. 3).

At time T4, the rotation of the motor 12 is stopped. That is, the vehicle is stopped. After time T4, discharge current flows out from the main battery 5 by the amount of consumption by the auxiliary machine. The fact that the measurement value IB of the current sensor 6 is a small positive value IB1 in a period from time T4 to T5 indicates that phenomenon.

It is assumed that after time T5, the measurement value IB of the current sensor 6 has become a smaller value (negative value) IB2 for some, reason. The negative measurement value IB2 means that charging current is flowing into the main battery 5. After time T4, however, the motor 12 for generating electric power remains stopped and there is no device supplying charging current to the main battery 5. Therefore, it is made evident that the measurement value IB2 after time T5 is not a normal value. When a duration time, during which the measurement value IB2 of the current sensor 6 is smaller than the current threshold IB_th (that is, a state in which a charging current larger than a predetermined current threshold is flowing into the main battery 5), continues for a predetermined time threshold dT_th (time T6), the controller 4 determines that a fault has occurred in the current sensor 6 and turns ON an error flag. In the meantime, “turning ON the error flag” corresponds to step S8 in the flow chart shown in FIG. 2.

As described above, the hybrid vehicle 100 of the present embodiment includes a logic for checking a fault in the current sensor 6 for measuring the charging/discharging current to/from the main battery 5. In a situation where the main battery 5 is connected to the drive system (that is, in a state in which the main switch 3 is at the ON position such that the system main relay 7 is closed) and no charging current could flow into the main battery 5 (i.e., in a state in which the power generation motor 12 is at a stop), the logic monitors the measurement, value IB of the current sensor 6, and, when the measurement value IB is negative (i.e., when the measurement value IB indicates that the charging current is flowing into the main battery 5), the logic determines that a fault has occurred in the current sensor 6 and outputs a message (error code) indicating the occurrence of the fault to a memory or the like.

Important points regarding technology of the present embodiment will be described. One of technical features of the present embodiment exists in that the situation, in which no charging current could flow into the main battery 5 under the conditions where the main battery 5 is connected to the circuits, such as the inverter, is specified. Because a number of devices that consume electric current are mounted on a vehicle, it is difficult to estimate how much discharging current will flow out from the main battery 5. Therefore, it is difficult to check soundness of the current sensor 6 based on the magnitude of discharging current that flows out of the main battery 5. Conversely, because the device for supplying the charging current to the main battery 5 is limited to the power generation motor, it is possible to conclude that no charging current will flow into the main battery 5 while the power generation motor is at a stop. In this way, in the hybrid vehicle 100 of the present embodiment, by specifying a particular situation and a range of values that any normal current sensor cannot indicate under such a particular situation while the main battery 5 and the inverter are connected to each other, the check of soundness of the current sensor is achieved.

In a vehicle capable of being charged from an external power supply (e.g., plug-in hybrid vehicle), when it is supplied with electric power from the external power supply, the measurement value IB of the current sensor 6 indicates that the charging current flows into the main battery 5. However, in general, while a plug for supplying electric power from outside is connected to a vehicle, although the system main relay 7 is closed to enable the charging of electric power, in order to prevent the vehicle form moving, it is prohibited to switch the main switch 3 in the driver's seat to the ON position. Alternatively, upon switching the main switch 3 to the ON position, the charging is stopped. Therefore, the technology of the present invention can be applied to a vehicle that can be charged from an external power supply.

In the present embodiment, an example in which the present invention has been applied to a hybrid vehicle including a traction motor and an engine has been described. In this embodiment, the traction motor serves as a power generation motor as well. The technology disclosed in this specification is applicable to a hybrid vehicle having a plurality of motors. In this case, the hybrid vehicle may include a dedicated traction motor and a dedicated power generation motor or may be such that a plurality of motors serve for traveling and power generation. Additionally, the technology disclosed in this specification is applicable also to an electric vehicle including no engine (so-called pure electric vehicle).

Although an embodiment of the present invention has been described in detail above, this is only exemplification and the scope of claims is not limited to the embodiment. The technology described in the claims includes various modifications and alterations of the embodiment exemplified above.

What is claimed is:

1. An electric vehicle comprising:
a battery that stores electric power to be supplied to a traction motor;
a current sensor that measures a charging current and a discharging current flowing to and from the battery; and
a controller configured to monitor a measurement value of the current sensor during a period of time, during which a main switch of the electric vehicle is at an ON position and a power generation motor is at a stop, and configured to, when the measurement value indicates that the charging current is flowing to the battery, output, to at least one of a display unit and a memory, data indicating that the charging current is flowing.

2. The electric vehicle according to claim 1, wherein
the main switch is provided at a driver's seat of the electric vehicle.

3. The electric vehicle according to claim 1, wherein,
the power generation motor is the traction motor.

4. The electric vehicle according to claim 1, wherein
the controller is configured to output, to the at least one of the display unit and the memory, data indicating that the charging current is flowing, provided that the measurement value of the current sensor indicates, for a longer time than a predetermined time threshold during the period of time, that a charging current larger than a predetermined current threshold is flowing to the battery.

5. A method of diagnosing a current sensor, provided on an electric vehicle including a battery, that measures a charging current and a discharging current flowing to and from the battery that stores electric power to be supplied to a traction motor, the method comprising:
monitoring a measurement value of the current sensor during a period of time, during which a main switch of the electric vehicle is at an ON position and a power generation motor is at a stop; and,
when the measurement value indicates that the charging current is flowing to the battery, outputting, to at least one of a display unit and a memory, data indicating that the charging current is flowing.

6. The method according to claim 5,
the main switch is provided at a driver's seat of the electric vehicle.

7. The method according to claim 5,
the power generation motor is the traction motor.

8. The method according to claim 5, wherein
the outputting is performed, provided that the measurement value of the current sensor indicates, for a longer time than a predetermined time threshold during the period of time, that a charging current larger than a predetermined current threshold is flowing to the battery.
